(19) United States
(12) Patent Application Publication
(10) Pub. No.: US 2008/0029855 A1
(43) Pub. Date: Feb. 7, 2008

(54) Lead Frame and Fabrication Method thereof

(76) Inventor: Yi-Ling Chang, Taipei City (TW)

Correspondence Address: HDSL, 4331 STEVENS BATTLE LANE, FAIRFAX, VA, 22033, US

(21) Appl. No.: 11/462,377

(22) Filed: Aug. 4, 2006

(51) Int. Cl. H01L 23/495

(52) U.S. Cl. 257/666

(57) ABSTRACT

A lead frame and a fabrication method thereof includes a metallic plate locally fabricated in double sides to form accurately aligned and closely spaced circuits. The metallic plate is also locally fabricated in single side to form patterned trenches. A filling material is filled into the trenches to provide extra mechanical support and separate the metallic plate into a plurality of conductive regions or regions with special electric properties. It can overcome the conventional problems in lead frame fabrication and has the advantages of a superior heat-dissipating ability, multi-leads and diversified applications.

### BACKGROUND OF THE INVENTION

1. Field of the Invention

The present invention relates to a lead frame fabrication technology, particularly to a lead frame and a fabrication method thereof, wherein the lead frame has extra mechanical support, and the lead frame also has a plurality of conductive regions or regions with special electric properties.

2. Description of the Related Art

The packaging of electronic elements is to transfer signals and power, provide a heat-dissipating path, and provide structural protection and support. In the back-end process of semiconductor fabrication, the lead frame and IC substrate are used to bridge the IC chip and external circuits and transmit the electronic signals between the chip and external systems.

With the promotion of chip function, the required I/O leads also greatly increase. However, the leads can only extend from four sides of a lead frame, and such a method cannot always provide sufficient leads. Thus, an alternative packaging method was proposed, wherein a PCB (Printed Circuit Board) is used as the chip carrier, and the array of solder balls is arranged on the bottom surface of the chip carrier and used to replace the leads extending from four sides of a lead frame. Such a packaging method is advantaged in that more leads can be arranged in the same area; thus, the dimension of a packaging structure can be reduced. However, with the ever-increasing power consumption, heat dissipation becomes a problem hard to overcome.

With the simplified circuit design benefiting from the SOC (System On Chip) trend, some CSP (Chip Scale Package) packages turn to utilize a lead frame to meet the requirement of heat dissipation. Such a tendency breeds the requirement for a packaging structure with the circuit complexity between a CSP package and a lead frame, such as the QFN (Quad Flat No lead) package. However, it is not so easy to utilize a traditional lead frame to implement the circuits asymmetrical in the upper and lower surfaces. In such a case, the traditional lead frame will meet the following problems: 1. difficulty in fabricating half-etching circuits, 2. circuit distortion during molding, and 3. overflow resin pollution in leads during molding. Accordingly, the present invention proposes a new lead frame and a fabrication method thereof to overcome the abovementioned problems.

### SUMMARY OF THE INVENTION

The primary objective of the present invention is to provide a fabrication method for a lead frame to effectively solve the conventional fabrication and packaging problems in a lead frame, wherein a double-side etching technology, a mechanical depth control technology or a casting technology is used to fabricate circuits with finer spacings and obtain a precise alignment; a localized single-side etching procedure is used to fabricate trenches, and the trenches/through-trenches are filled with a filling material to obtain a structural support; next, circuits are formed in the other sides of the trenches.

Another objective of the present invention is to provide a fabrication method for a lead frame, wherein the circuits on a lead frame can be diversified with a filling material or a support structure, and the lead frame can thus meet the requirements of various semiconductor packages.

Further another objective of the present invention is to provide a fabrication method for a lead frame, wherein a column-type conductor interconnecting the upper and lower surfaces can be directly fabricated, and a filling material is filled into the trenches; hole-drilling and through-hole electroplating procedures used in PCB are unnecessary in the method of the present invention; thus, the wire routing procedure can be saved, and the dimension of the chip carrier can be reduced; in the method of the present invention, more available area can be obtained in the same packaging dimension, and the lead installation positions are not limited to the perimeter of the lead frame; thus, the lead frame fabricated according to the present invention is equal to an LGA (Land Grid Array) lead frame.

The present invention proposes an embodiment of a lead frame, wherein patterned trenches and patterned through-trenches are formed in a metallic plate, and a filling material is filled into the patterned trenches or the patterned through-trenches to form a lead frame with a plurality of conductive regions.

The present invention proposes an embodiment of a fabrication method for a lead frame, wherein a metallic plate is provided firstly; next, a plurality of through-trenches and lower/upper trenches are fabricated with an etching procedure, a mechanical depth control procedure or a casting procedure; next, a filling material is selectively filled into the through-trenches and the lower/upper trenches; next, a plurality of conductive layers are formed on the upper and lower surfaces of the metallic plate; and then, a plurality of upper/lower trenches are formed on the surface of the metallic plate.

The present invention further proposes an embodiment of a fabrication method for a lead frame, wherein a metallic plate is provided firstly; next, a plurality of through-trenches and lower/upper trenches are fabricated with an etching procedure, a mechanical depth control procedure or a casting procedure, and a filling material is selectively filled into the through-trenches and the lower/upper trenches; next, a plurality of through-trenches and upper/lower trenches are formed on the surface of the metallic plate with an etching procedure, a mechanical depth control procedure or a casting procedure, and a filling material is selectively filled into the through-trenches and the upper/lower trenches; and then, a plurality of conductive layers are formed on the upper and lower surfaces of the metallic plate.

To enable the structural characteristics and accomplishments of the present invention to be easily understood, the preferred embodiments of the present invention are to be described in detail in cooperation with the attached drawings.

### BRIEF DESCRIPTION OF THE DRAWINGS

FIG. 1(a) to FIG. 1(j2) are sectional views schematically showing the steps of the fabrication method according to one embodiment of the present invention;

FIG. 2(a) to FIG. 2(c2) are sectional views schematically showing the steps of the fabrication method according to another embodiment of the present invention;

FIG. 3 is a diagram schematically showing the pattern of the patterned resist layer on the upper surface of a metallic plate;

FIG. 4 is a diagram schematically showing the pattern of the patterned resist layer on the lower surface of a metallic plate;

FIG. 5(a) to FIG. 5(f4) are sectional views schematically showing the steps of the fabrication method according to further another embodiment of the present invention;

FIG. 6 is a diagram schematically showing the step of forming an accommodation basin is integrated with the step of fabricating upper trenches with an etching method; and

FIG. 7(a) and FIG. 7(b) are diagrams schematically showing the embodiment that a plurality of metallic bumps are formed and used as the interface to connect with external systems.

### DETAILED DESCRIPTION OF THE INVENTION

The present invention pertains to a lead frame and a fabrication method thereof, wherein a metallic-plate lead frame, which is to be used as a semiconductor carrier, is fabricated via a selective etching technology/a depth control fabrication technology/a casting technology, a double-side etching technology and a material-filling technology; the metallic-plate lead frame has a superior heat-dissipating effect and can apply to a multi-lead semiconductor packaging; thereby, the present invention can overcome the conventional problems in lead frame fabrication and packaging.

It is to be clarified beforehand: the present invention is characterized in utilizing through-trenches, upper trenches, lower trenches and a filling material to form a metallic lead frame; however, the present invention is not limited by the through-trench, the upper trench and the lower trench exemplified in the specification, and any equivalent modification and variation with respect to the through-trench, the upper trench or the lower trench is to be also included within the scope of the present invention.

Below, an embodiment, wherein the through-trenches and the lower trenches are firstly formed, is used to exemplify the fabrication method of the present invention.

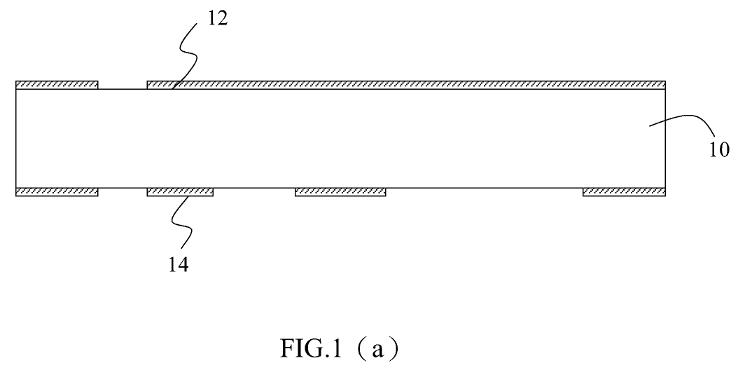

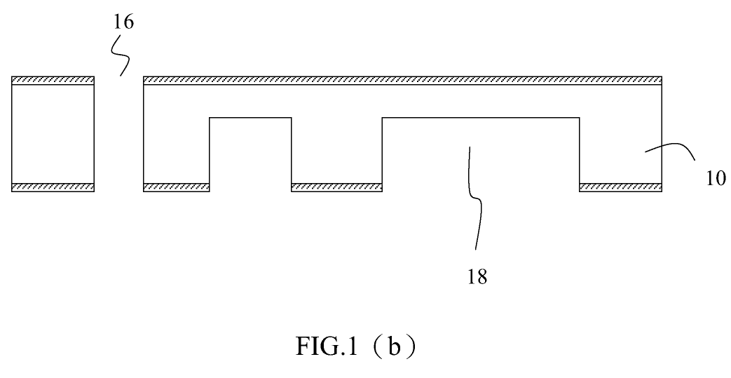

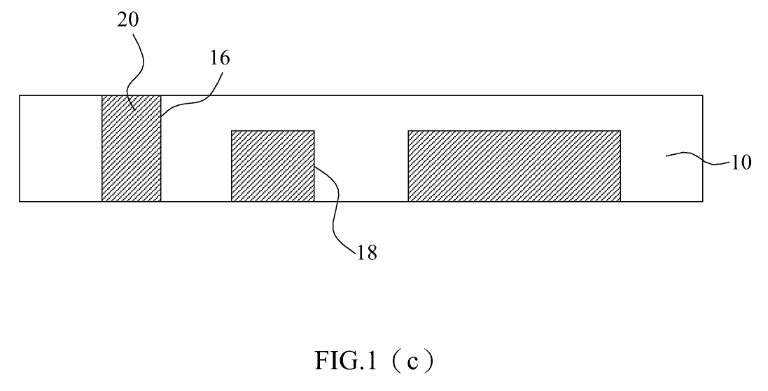

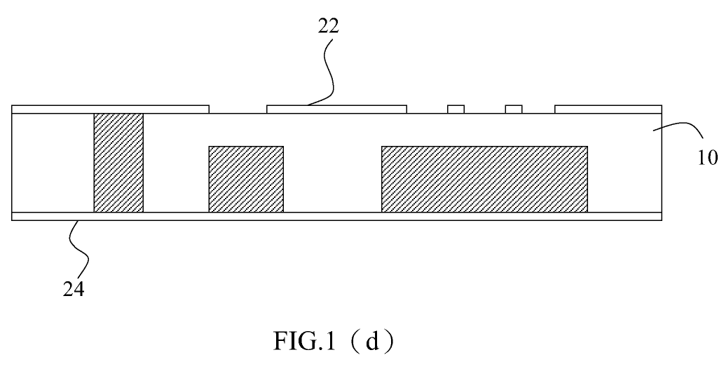

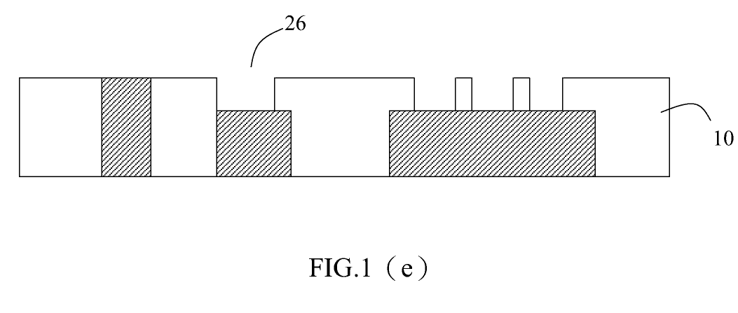

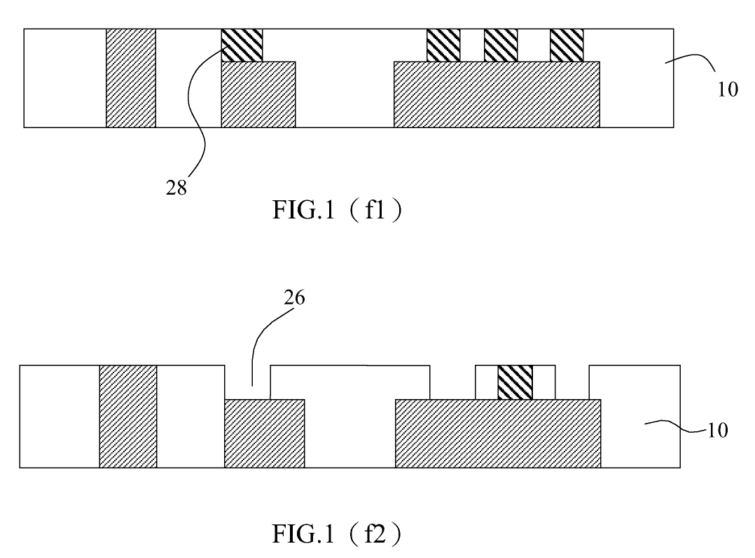

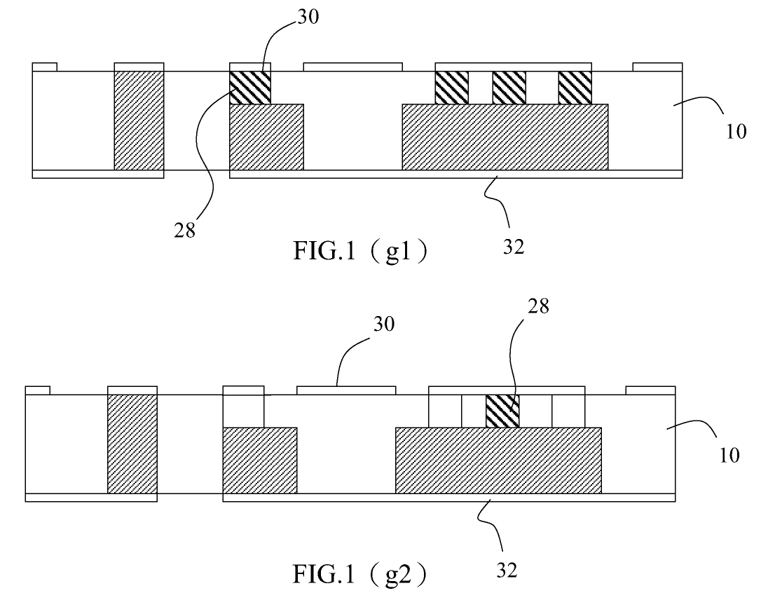

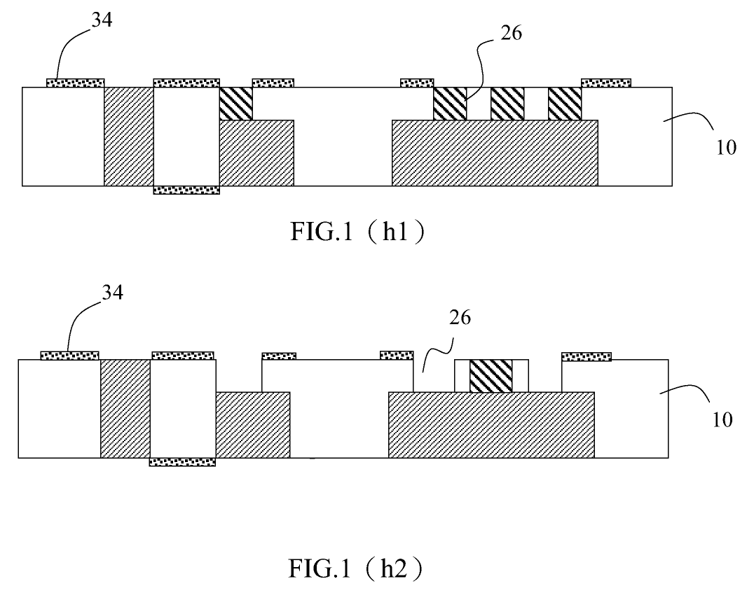

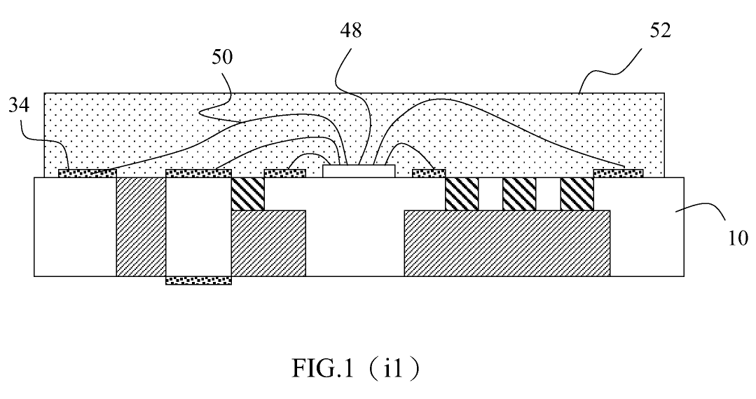

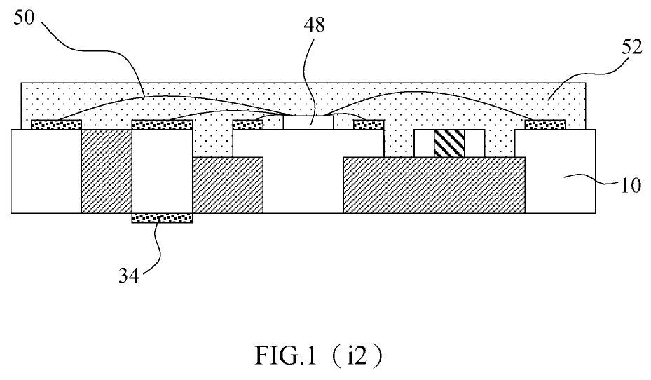

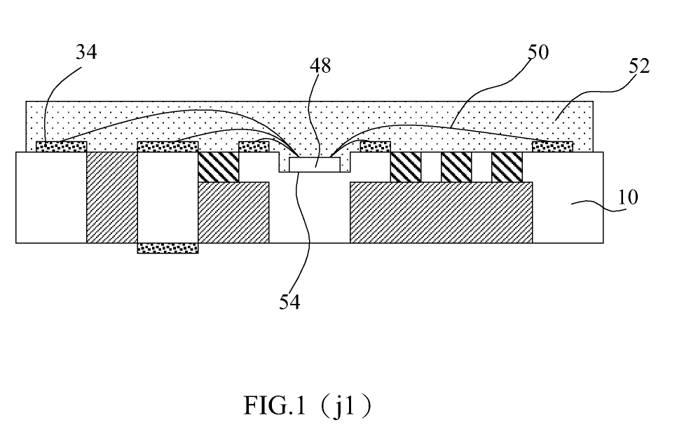

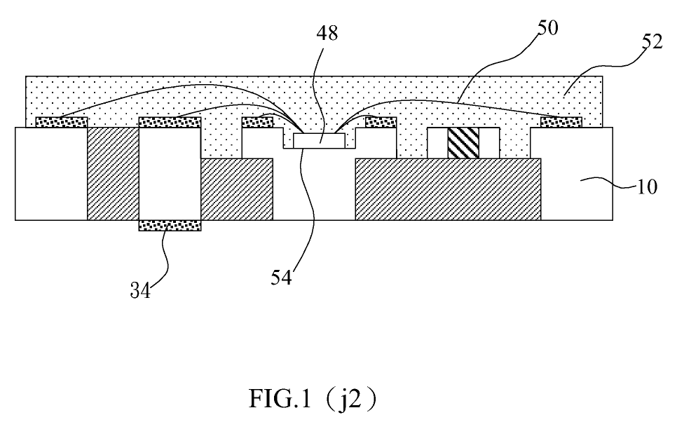

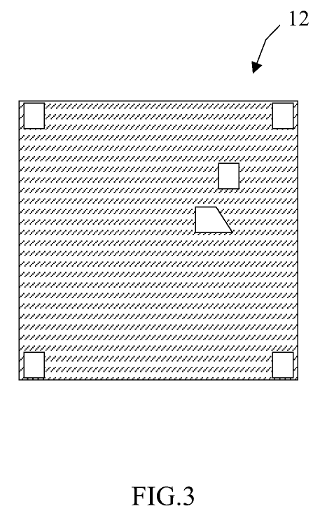

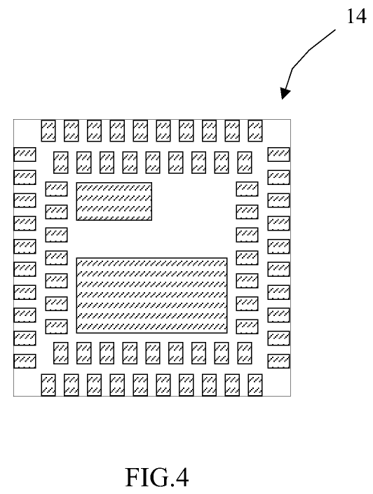

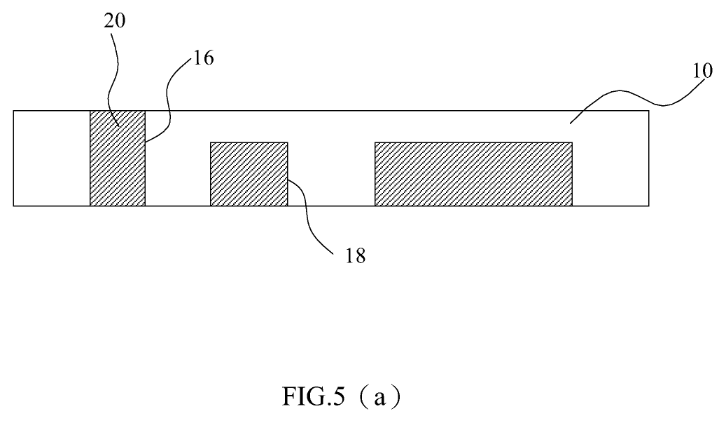

Firstly, as shown in FIG. 1(a), a patterned resist layer 12 and a patterned resist layer 14 is respectively formed on the upper surface and the lower surface of a metallic plate 10. The patterns of the patterned resist layer 12 and the patterned resist layer 14 are respectively shown in FIG. 3 and FIG. 4.

Next, as shown in FIG. 1(b), the metallic plate 10 is etched to form a through-trench 16 and a lower trench 18 with the patterned resist layer 12 and the patterned resist layer 14 being the masks. The wet etching method is preferred to etch the metallic plate 10. The wet etching method is more likely to obtain a straighter trench wall, which benefits the formation of a finer and denser circuit and a better alignment. Then, the patterned resist layer 12 and the patterned resist layer 14 are removed. The trench and the through-trench may also be fabricated in cooperation with a depth control technology or a casting technology.

Next, as shown in FIG. 1(c), a material-filling procedure is undertaken, and a filling material 20/supporters are filled/pressed into the through-trench 16 and the lower trench 18. Next, the filling material 20/supporters are planarized with a polishing procedure lest the filling material 20/supporters cover the areas where circuits or conductive layers are to be formed. Thereby, an elaborate circuit and a lower surface circuit are obtained. The filling material 20 may be a resin, a silver paste, a copper paste or a carbon paste, which is insulating or can change electric properties.

Next, as shown in FIG. 1(d), a patterned resist layer 22 and a patterned resist layer 24 are respectively formed on the upper surface and the lower surface of the metallic plate 10. Next, as shown in FIG. 1(e), the metallic plate 10 is etched to form a plurality of trenches 26 with the patterned resist layers 22 and 24 being the masks, and then, the patterned resist layers 22 and 24 are removed. The etching procedure may be undertaken with a selective etching technology or a depth control technology.

Next, a filling material 28/supporters are filled/pressed into the trenches 26, and then, the filling material 28/supporters are planarized with a polishing procedure to form the upper surface circuits shown in FIG. 1(f1) or FIG. 1(f2).

Next, as shown in FIG. 1(g1) or FIG. 1(g2), patterned anti-plating layers 30 and 32 or solder masks are respectively formed on the metallic plate 10, and the patterned anti-plating layers 30 and 32 or solder masks are used to define a plurality of externally-connected conductive layers, which are to be connected to external systems. Next, as shown in FIG. 1(h1) or FIG. 1(h2), a plurality of externally-connected conductive layers 34, which are to enhance the conductivity of conductive regions, are formed on the upper and lower surfaces of the metallic plate 10 with the patterned anti-plating layers 30 and 32 or solder masks being masks, and then, the patterned anti-plating layers 30 and 32 are removed. If the solder masks are used, the solder mask will not be removed. The conductive layer may be fabricated via various metallic surface treatment technologies, such as the electroless tin deposition technology, the tin plating technology, the electroless silver deposition technology, the silver electroplating technology, the nickel-gold plating technology, the electroless nickel-palladium-gold deposition technology, and the electroless nickel immersion gold technology.

After the lead frame is completed, the process proceeds to a chip-attachment procedure. In this embodiment, as shown in FIG. 1(i1) and FIG. 1(i2), the central region of the metallic plate 10 is predetermined to be the chip-attachment area, and wires 59 are used to interconnect a chip 48 and the externally-connected conductive layers 34, and then, an encapsulant 52, which is usually made of an epoxy resin, is applied to the upper surface of the metallic plate 10 to cover the chip 48 and the wires 52 and provide a mechanical protection for them lest they be damaged by external force. Further, as shown in FIG. 1(j1) and FIG. 12), an accommodation basin 54 may be formed in the central region of the metallic plate 10, and the chip 48 is arranged inside the accommodation basin 54; thereby, the overall thickness of the packaging structure can be reduced.

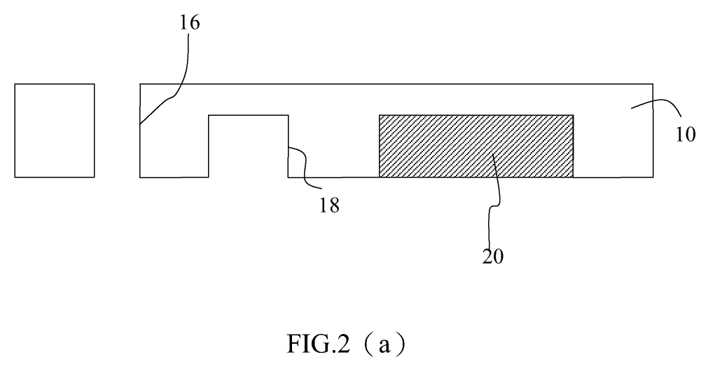

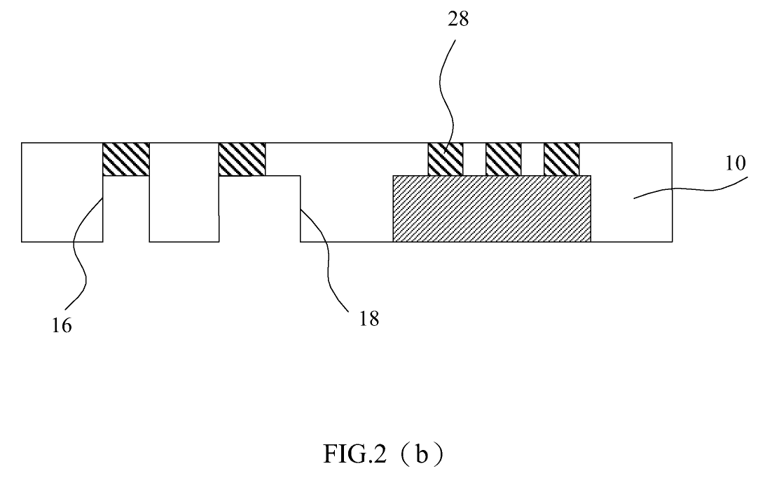

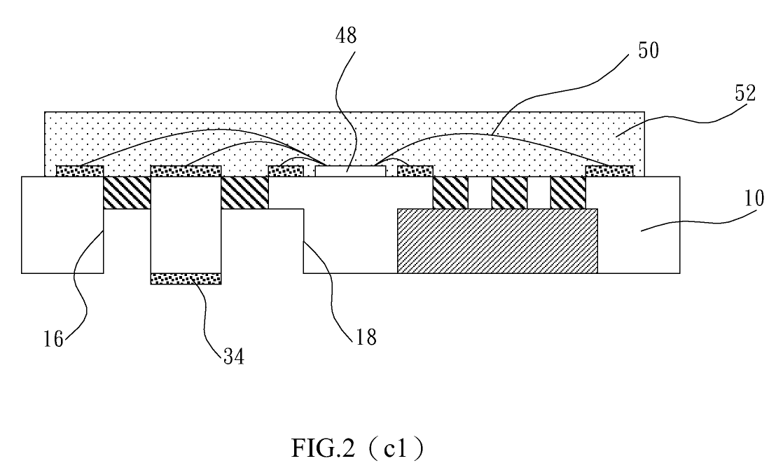

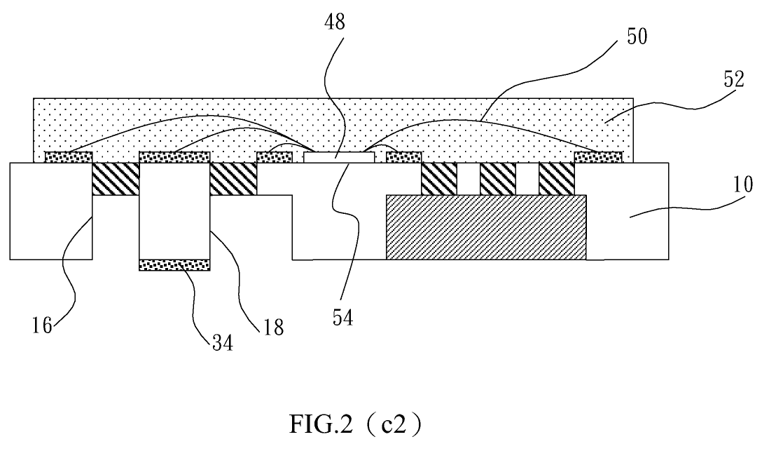

In contrast to the abovementioned procedure of filling/pressing the filling material/supporters into all the through-trench 16 and the lower trenches 18, the filling material/supporters may be selectively filled/pressed according to the conduction requirements of different areas on the metallic plate 10. As shown in FIG. 2(a), none supporter/filling material 20 exists in the through-trench 16 and a portion of the lower trenches 18. Next, similarly to the abovementioned procedures, a plurality of upper trenches 26 is formed on the metallic plate 10, and the filling material 28/supporters are selectively filled/pressed into the upper trenches 26, and then, the filling material 28/supporters are planarized; thus, a plurality of upper surface circuits is obtained, as shown in FIG. 2(b). Next, a plurality of the externally-connected conductive layers 34 is formed on the upper and lower surfaces of the metallic plate 10, and then, a chip-attachment procedure and an encapsulation procedure are sequentially undertaken to form the structure shown in FIG. 2(c1) or FIG. 2(c2).

In addition to the abovementioned embodiment, the present invention also proposes an embodiment, wherein a through-trench or lower/upper trenches are firstly formed; next, a filling material is filled into the through-trench or the trenches and then planarized; next, a plurality of conductive layers is formed on the specified areas of the upper and lower surface of the metallic plate; and then, upper/lower trenches and circuits are sequentially formed.

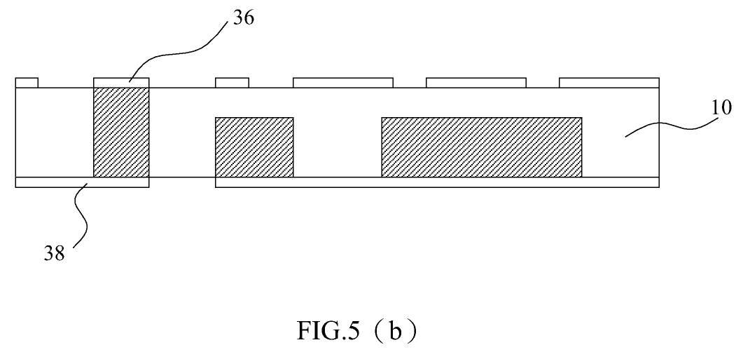

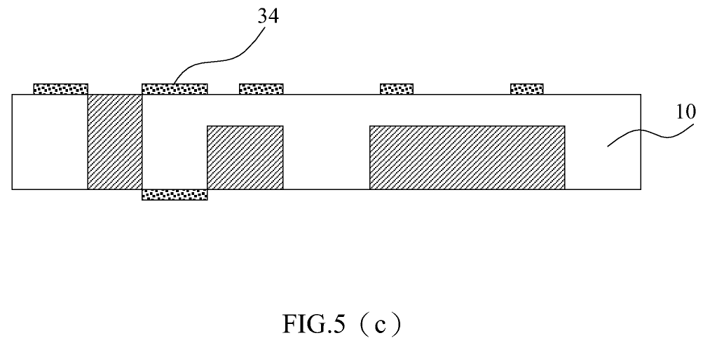

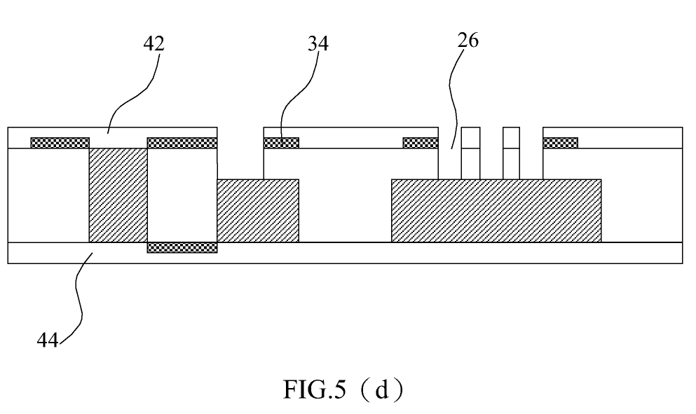

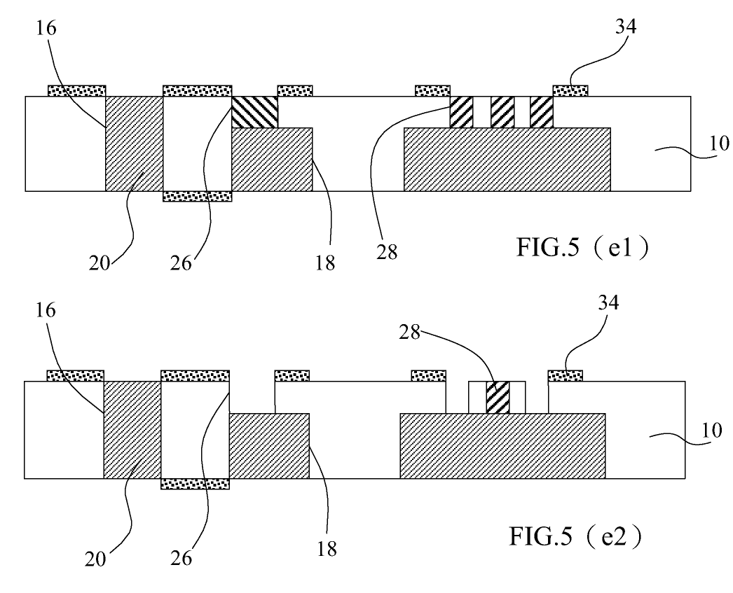

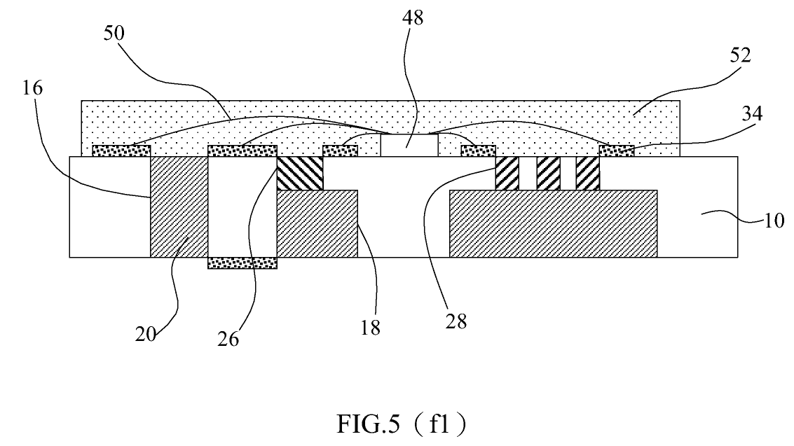

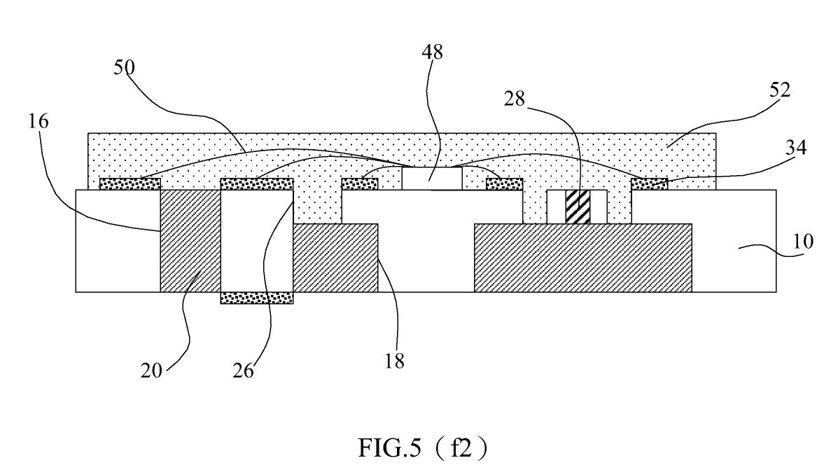

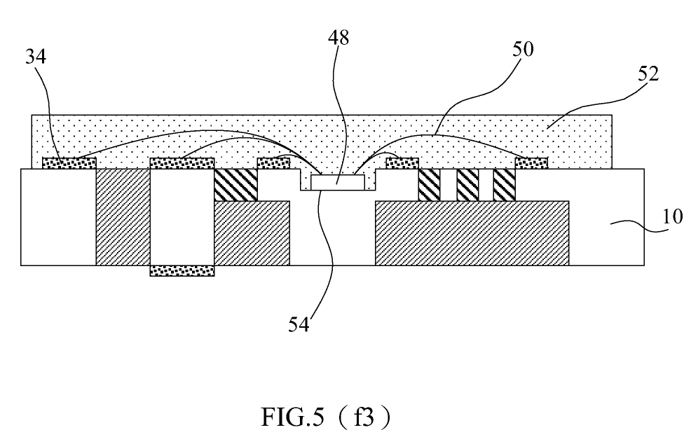

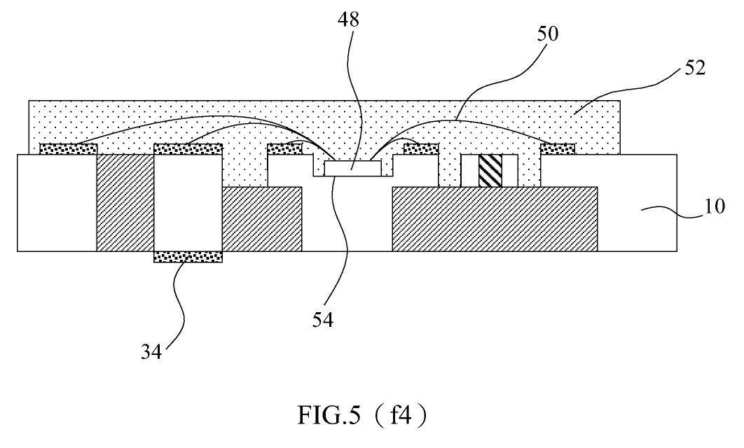

Herein, an embodiment is to be described, wherein a through-trench or lower trenches are firstly formed, and then, the material-filling procedure, the conductive layer forming procedure and the upper trench forming procedure are sequentially undertaken. Firstly, according to the abovementioned procedures shown in from FIG. 1(a) to FIG. 1(c), the through-trench 16 and the lower trenches 18 having the filling material thereinside shown in FIG. 5(a) are fabricated.

Next, as shown in FIG. 5(b), patterned anti-plating layers 36 and 38 are respectively formed on the upper and lower surfaces of the metallic plate 10 and used to define a plurality of externally-connected conductive layers. Next, as shown in FIG. 5(c), a plurality of externally-connected conductive layers 34, which are to enhance the conductivity of conductive regions, is formed on the upper and lower surfaces of the metallic plate 10 with the anti-plating layers 36 and 38 being masks, and then, the patterned anti-plating layers 36 and 38 are removed. The externally-connected conductive layer 34 may be fabricated via various metallic surface treatment technologies, such as the electroless tin deposition technology, the tin plating technology, the electroless silver deposition technology, the silver electroplating technology, the nickel-gold plating technology, the electroless nickel-palladium-gold deposition technology, and the electroless nickel immersion gold technology.

Next, as shown in FIG. 5(d), patterned resist layers 42 and 44 are respectively formed on the metallic plate 10 and used to define upper trenches, and the metallic plate 10 is etched to form the upper trenches 26 with the patterned resist layers 42 and 44 and the externally-connected conductive layers 34 being masks; then, the patterned resist layers 42 and 44 are removed. Next, as shown in FIG. 5(e1) and FIG. 5(e2), a filling material 28/supporters are selectively filled/pressed into the upper trenches 26 to obtain a lead frame, which integrates the advantages of the conventional PCB and lead frame.

Next, a chip 48 is attached to the metallic plate 10, and wires 50 are used to interconnect the chip 48 and the externally-connected conductive layers 34, and then, an encapsulant 52 is applied to cover the chip 48, the wires 50 and the externally-connected conductive layers 34; thereby, a structure shown in FIG. 5(f1) or FIG. 5(f2) is obtained. Otherwise, an accommodation basin 54 for the chip 48 may be firstly formed, and then, the chip-attachment, wire connecting and encapsulating procedures are sequentially undertaken to form a structure shown in FIG. 5(f3) or FIG. 5(f4).

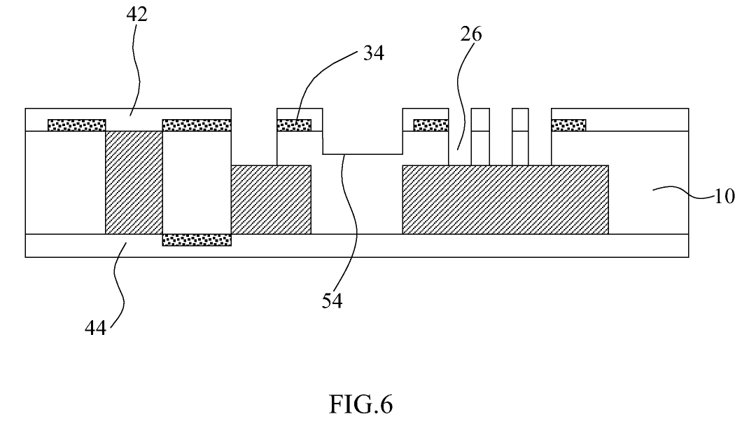

Further, the fabrication procedure of the accommodation basin 54 may be combined with the fabrication procedure of the upper trenches 26, wherein the patterned resist layers 42 and 44 are respectively formed on the upper and lower surfaces of the metallic plates 10 and used to define the upper trenches 26 and the accommodation basin 54, and then, with the patterned resist layers 42 and 44 and the externally-connected conductive layers 34 being masks, the metallic plates 10 is etched to form the upper trenches 26 and the accommodation basin 54 shown in FIG. 6. Next, the selective material-filling procedure and the chip attachment procedure are sequentially undertaken. The succeeding procedures are the same as those described above and will not be described repeatedly here.

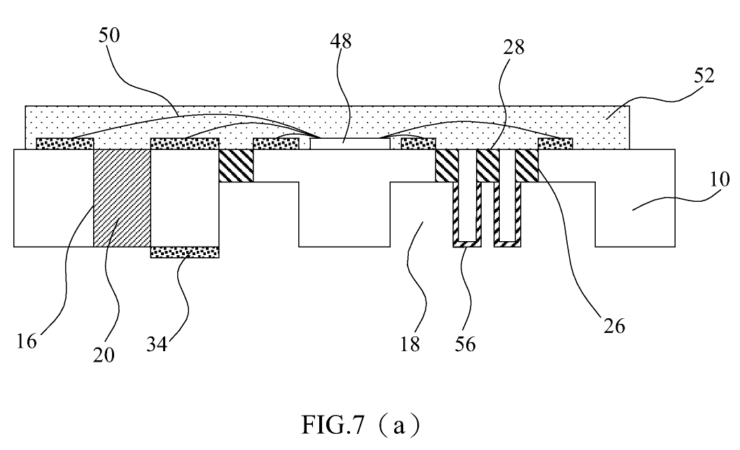

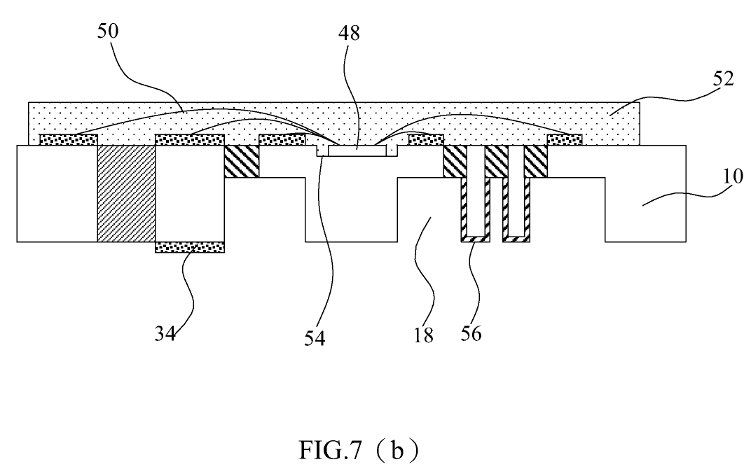

Refer to FIG. 7(a) and FIG. 7(b) for another embodiment of the present invention. In this embodiment, none filling is filled into the selected lower trenches, but a plurality of metallic bumps 56 are formed inside those selected lower trenches. The metallic bumps 56 replace the conventional solder bumps and function as the interfaces to connect with external systems; thereby, the problem of joining different metals is less likely to occur, and the reliability of the entire element is promoted. Further, the solder-ball fabrication steps can be decreased, and the cost and defective fraction of the packaging process is thus reduced.

In summary, the present invention proposes a lead frame and a fabrication method thereof, wherein a double-side etching technology is used to form denser circuits, and a multi-stage etching technology, a depth control technology and a material-filling technology are used to overcome the conventional problems in the fabrication and packaging of lead frames.

The present invention has the following advantages:
1. The circuit of the lead frame of the present invention can be diversified via utilizing the filling material/supporters, and the lead frame of the present invention can extensively apply to various semiconductor packages.
2. A plurality of metallic bumps may be fabricated beforehand in the lead frame of the present invention, and the reliability of the packaged element is thus promoted, and the cost and defective fraction of semiconductor packaging is thus reduced.
3. The spaces between leads have been filled with the filling material in the present invention; thus, the overflow resin on SMT (Surface Mount Technology) pads will no more occur in the molding procedure, and the steps and cost of the packaging process can be reduced, and the yield is promoted.
4. The overall thickness of the semiconductor package can be reduced via the accommodation basin formed in the lead frame of the present invention.

Although the present invention has been explained in relation to its preferred embodiment, it is to be understood that other modifications and variation can be made without departing the spirit and scope of the invention as hereafter claimed.

What is claimed is:

1. A lead frame, comprising:
a metallic plate, wherein a plurality of patterned trenches and through-trenches are formed thereon; and
a filling material filled into said patterned trenches or said patterned through-trenches of said metallic plate to separate said metallic plate into a plurality of conductive regions.

2. The lead frame according to claim 1, wherein said filling material is an insulating material and used to separate said metallic plate into the plurality of conductive regions.

3. The lead frame according to claim 1, wherein said filling material is a conductive material and filled into specified patterned trenches and through-trenches of said metallic plate to form regions having special electrical properties.

4. The lead frame according to claim 2, wherein the surfaces of the plurality of said conductive regions are further surface-treated to form a conductive layer.

5. The lead frame according to claim 4, wherein said conductive layer is fabricated with a metallic surface treatment technology, and said metallic surface treatment technology is an electroless tin deposition technology, a tin plating technology, a solder plating technology, a hot air solder leveling technology, an electroless silver deposition technology, a silver electroplating technology, a nickel-gold plating technology, an electroless nickel-palladium-gold deposition technology, or an electroless nickel immersion gold technology.

6. The lead frame according to claim 1, wherein said trenches or said through-trenches are fabricated with a plurality of wet etching procedures, dry etching procedures, casting procedures or depth control procedures.

7. The lead frame according to claim 1, wherein said trenches or said through-trenches are fabricated with a plurality of selective etching procedures.

8. The lead frame according to claim 1, wherein said trenches or said through-trenches are fabricated with a plurality of depth control procedures.

9. The lead frame according to claim 1, wherein said trenches or said through-trenches are fabricated with a casting procedure.

10. The lead frame according to claim 1, wherein one or a plurality of accommodation basins are further formed in a predetermined chip-attachment region of said metallic plate and used to accommodate one or a plurality of chips.

11. The lead frame according to claim 1, wherein a solder mask is selectively formed on the surface of said metallic plate or above said filling material.

12. The lead frame according to claim 1, wherein said filling material is an insulating material or a material able to change electric properties, and said filling material is selected from the group consisting of resin, silver paste, aluminum paste, copper paste, carbon paste and ceramic material.

13. The lead frame according to claim 1, wherein a plurality of metallic bumps are further formed on a lower surface of said metallic plate and used to interconnect semiconductor element and external systems.

14. A fabrication method for a lead frame, comprising the following steps:
providing a metallic plate:
fabricating said metallic plate to form a plurality of through-trenches and lower/upper trenches;
selectively filling said through-trenches and said lower/upper trenches with a filling material;
forming a plurality of conductive layers on upper and lower surfaces of said metallic plate; and
fabricating said metallic plate to form a plurality of upper/lower trenches on the surface of said metallic plate, and selectively filling said upper/lower trenches with the filling material.

15. The fabrication method for a lead frame according to claim 14, wherein the step of fabricating said metallic plate is undertaken with a plurality of wet etching procedures, dry etching procedures, casting procedures, or depth control procedures.

16. The fabrication method for a lead frame according to claim 14, wherein said lower/upper trenches or said through-trenches are fabricated with a plurality of selective etching procedures.

17. The fabrication method for a lead frame according to claim 14, wherein said lower/upper trenches or said through-trenches are fabricated with a plurality of depth control procedures.

18. The fabrication method for a lead frame according to claim 14, wherein said lower/upper trenches or said through-trenches are fabricated with a casting procedure.

19. The fabrication method for a lead frame according to claim 14, wherein said conductive layers are fabricated with a metallic surface treatment technology, and said metallic surface treatment technology is an electroless tin deposition technology, a tin plating technology, a solder plating technology, a hot air solder leveling technology, an electroless silver deposition technology, a silver electroplating technology, a nickel-gold plating deposition technology, an electroless nickel-palladium-gold deposition technology, or an electroless nickel immersion gold technology.

20. The fabrication method for a lead frame according to claim 14, wherein said filling material is an insulating material or a material able to change electric properties, and said filling material is selected from the group consisting of resin, silver paste, aluminum paste, copper paste, carbon paste and ceramic material.

21. A fabrication method for a lead frame, comprising the following steps:
providing a metallic plate and fabricating said metallic plate to form a plurality of through-trenches and lower/upper trenches;
selectively filling said through-trenches and said lower/upper trenches with a filling material;
fabricating said metallic plate to form a plurality of upper/lower trenches on the surface of said metallic plate and selectively filling said upper/lower trenches with the filling material; and
forming a plurality of conductive layers on the upper/lower surfaces of said metallic plate.

22. The fabrication method for a lead frame according to claim 21, wherein the step of fabricating said metallic plate is undertaken with a plurality of wet/dry etching procedures, casting procedures, or depth control procedures.

23. The fabrication method for a lead frame according to claim 21, wherein said lower/upper trenches or said through-trenches are fabricated with a plurality of selective etching procedures.

24. The fabrication method for a lead frame according to claim 21, wherein said lower/upper trenches or said through-trenches are fabricated with a plurality of depth control procedures.

25. The fabrication method for a lead frame according to claim 21, wherein said lower/upper trenches or said through-trenches are fabricated with a casting procedure.

26. The fabrication method for a lead frame according to claim 21, wherein said conductive layer is fabricated with a metallic surface treatment technology to provide the electric connection for said lead frame and a semiconductor chip, and said metallic surface treatment technology is an electroless tin deposition technology, a tin electroplating technology, a solder plating technology, a hot air solder leveling technology, an electroless silver deposition technology, a silver electroplating technology, an electroless nickel-gold plating deposition technology, an electroless nickel-palladium-gold deposition technology, or an electroless nickel immersion gold technology.

27. The fabrication method for a lead frame according to claim 21, wherein said filling material is an insulating material or a material able to change electric properties, and said filling material is selected from the group consisting of resin, silver paste, aluminum paste, copper paste, carbon paste and ceramic material.

28. A semiconductor package element, comprising:
a metallic plate, wherein a plurality of patterned trenches and through-trenches are formed thereon;
a filling material filled into said patterned trenches or said patterned through-trenches of said metallic plate and used to separate said metallic plate into a plurality of predetermined chip-attachment regions and a plurality of conductive regions; and
one or a plurality of chips arranged on said predetermined chip-attachment regions of said metallic plate and electrically connected to said conductive regions.

29. The semiconductor package element according to claim 28, wherein the surfaces of the plurality of said conductive regions are further surface-treated to form a conductive layer.

30. The semiconductor package element according to claim 28, wherein said conductive layer is fabricated with a metallic surface treatment technology to provide the electric connection for said semiconductor package element and a semiconductor chip, and said metallic surface treatment technology is an electroless tin deposition technology, a tin plating technology, a solder plating technology, a hot air solder leveling technology, an electroless silver deposition technology, a silver electroplating technology, an electroless nickel-gold plating deposition technology, an electroless nickel-palladium-gold deposition technology, or an electroless nickel immersion gold technology.

31. The semiconductor package element according to claim 28, further comprising an encapsulant used to cover said chip.

32. The semiconductor package element according to claim 28, wherein said patterned trenches or said through-trenches are fabricated with a plurality of selective etching procedures.

33. The semiconductor package element according to claim 28, wherein said patterned trenches or said through-trenches are fabricated with a plurality of depth control procedures.

34. The semiconductor package element according to claim 28, wherein said trenches or said through-trenches are fabricated with a casting procedure.

35. The semiconductor package element according to claim 28, wherein said conductive layer is fabricated with a surface treatment technology to provide the electric connection for a lead frame and a semiconductor chip, and said surface treatment technology is an electroless tin deposition technology, a tin plating technology, a solder electroplating technology, a hot air solder leveling technology, an electroless silver deposition technology, a silver electroplating technology, an electroless nickel-gold plating deposition technology, an electroless nickel-palladium-gold deposition technology, or an electroless nickel immersion gold technology.

36. The semiconductor package element according to claim 28, wherein said filling material is an insulating material or a material able to change electric properties, and said filling material is selected from the group consisting of resin, silver paste, aluminum paste, copper paste, carbon paste and ceramic material.

37. The semiconductor package element according to claim 28, wherein one or a plurality of accommodation basins is further formed in the predetermined chip-attachment region of said metallic plate and used to accommodate one or a plurality of chips.

38. The semiconductor package element according to claim 28, wherein one or a plurality of metallic bumps are further formed on a lower surface of said metallic plate and used to interconnect semiconductor element and external systems.
